(19) United States
(12) Patent Application Publication
(10) Pub. No.: US 2026/0130236 A1
(43) Pub. Date: May 7, 2026

(54) CHIP ON FILM PACKAGE AND ELECTRONIC DEVICE INCLUDING THE SAME

(71) Applicant: SAMSUNG ELECTRONICS CO., LTD., Suwon-si (KR)

(72) Inventors: NARAE SHIN, Suwon-si (KR); JEONG-KYU HA, Suwon-si (KR)

(73) Assignee: SAMSUNG ELECTRONICS CO., LTD., Suwon-si (KR)

(21) Appl. No.: 19/172,090

(22) Filed: Apr. 7, 2025

(30) Foreign Application Priority Data
Nov. 5, 2024 (KR) 10-2024-0155572

(51) Int. Cl. H01L 23/495; H01L 23/00

(52) U.S. Cl. CPC H10W 70/453; H10W 70/421; H10W 74/15; H10W 90/724; H10W 90/734

(57) ABSTRACT

A chip on film package may include: a substrate; a semiconductor chip on the substrate; first wires extending, on the substrate, to an edge of a first side of the substrate from a portion of the first wires overlapping with an edge of a first side of the semiconductor chip; second wires extending, on the substrate, to an edge of a second side of the substrate from a portion of the second wires overlapping with an edge of a second side of the semiconductor chip; first bumps connecting the first wires and the semiconductor chip; first dummy patterns spaced apart from at least some of the first bumps, the first dummy patterns being nearer than the first bumps to a center portion of the semiconductor chip, wherein the first dummy patterns are respectively spaced apart from first internal bumps, among the first bumps, in a second direction.

### CROSS-REFERENCE TO RELATED APPLICATION

This application claims priority to and the benefit of Korean Patent Application No. 10-2024-0155572, filed in the Korean Intellectual Property Office on Nov. 5, 2024, the disclosure of which is incorporated herein by reference in its entirety.

### BACKGROUND

### 1. Field Some embodiments of the present disclosure relate to a chip on film package.

### 2. Description of Related Art

To cope with the recent trend of miniaturization, thinning, and lightening of electronic products, as a high-density semiconductor chip mounting technology, a chip on film (COF) package technology using a flexible film substrate has been proposed. The COF package technology is attracting attention as a high-integration package technology because a semiconductor chip can be directly bonded to the film substrate by a flip-chip bonding method, can be connected to an external circuit through short leads, and can form a dense wiring pattern.

### SUMMARY

According to some embodiments of the present disclosure, a chip on film package for increasing reliability may be provided.

According to some embodiments of the present disclosure, a chip on film package may be provided and include: a substrate; a semiconductor chip on the substrate; first wires extending, on the substrate, to an edge of a first side of the substrate from a portion of the first wires overlapping with an edge of a first side of the semiconductor chip; second wires extending, on the substrate, to an edge of a second side of the substrate from a portion of the second wires overlapping with an edge of a second side of the semiconductor chip; first bumps connecting the first wires and the semiconductor chip; first dummy patterns spaced apart from at least some of the first bumps, the first dummy patterns being nearer than the first bumps to a center portion of the semiconductor chip, wherein the first bumps include: first external bumps spaced apart from each other in a first direction that is parallel to the edge of the first side of the semiconductor chip; and first internal bumps spaced apart from each other in the first direction, the first internal bumps being nearer than the first external bumps to the center portion of the semiconductor chip, and wherein the first dummy patterns are respectively spaced apart from the first internal bumps in a second direction that is perpendicular to the first direction.

According to some embodiments of the present disclosure, an electronic device may be provided and include: a printed circuit board; and a chip on film package including: an output pin on a first side of the chip on film package; and an input pin on a second side of the chip on film package, the input pin connecting the chip on film package and the printed circuit board; a substrate; a semiconductor chip on the substrate; first wires extending, on the substrate, to an edge of a first side of the substrate from a portion of the first wires overlapping with an edge of a first side of the semiconductor chip, wherein at least one of the first wires is connected to the output pin; second wires extending, on the substrate, to an edge of a second side of the substrate from a portion of the second wires overlapping with an edge of a second side of the semiconductor chip, wherein at least one of the second wires is connected to the input pin; first bumps connecting the first wires and the semiconductor chip; and first dummy patterns spaced apart from at least some of the first bumps, the first dummy patterns being nearer than the first bumps to a center portion of the semiconductor chip, wherein the first bumps include: first external bumps spaced apart from each other in a first direction that is parallel to the edge of the first side of the semiconductor chip; and first internal bumps spaced apart from each other in the first direction, the first internal bumps being nearer than the first external bumps to the center portion of the semiconductor chip, and wherein the first dummy patterns are respectively spaced apart from the first internal bumps in a second direction that is perpendicular to the first direction.

According to some embodiments of the present disclosure, a chip on film package may be provided and include: a substrate; a semiconductor chip on the substrate; first wires extending, on the substrate, to an edge of a first side of the substrate from a portion first of the first wires overlapping with an edge of a first side of the semiconductor chip; second wires extending, on the substrate, to an edge of a second side of the substrate from a portion of the second wires overlapping with an edge of a second side of the semiconductor chip; a first protection layer on at least a region of the first wires and the second wires; a second protection layer in a gap between the substrate and the semiconductor chip; first bumps connecting the first wires and the semiconductor chip; second bumps connecting the second wires and the semiconductor chip; and first dummy patterns spaced apart from at least some of the first bumps, the first dummy patterns being nearer than the first bumps to a center portion of the semiconductor chip, wherein the first bumps include: first external bumps spaced apart from each other in a first direction that is parallel to the edge of the first side of the semiconductor chip; and first internal bumps spaced apart from each other in the first direction, the first internal bumps being nearer than the first external bumps to the center portion of the semiconductor chip, and wherein each of the first dummy patterns include a quadrangular shape extending in a second direction that is perpendicular to the first direction, and the first dummy patterns are respectively spaced apart from the first internal bumps in the second direction.

According to some embodiments of the present disclosure, delamination of wires during a process for manufacturing a chip on film package may be reduced, and hence, the reliability of the chip on film package according to the embodiments may be increased.

### BRIEF DESCRIPTION OF DRAWINGS

FIG. 1 shows a perspective view of an electronic device including a chip on film package according to an embodiment.

FIG. 2 shows a block diagram of an electronic device including a chip on film package according to an embodiment.

FIG. 3 shows a top plan view of a chip on film package according to an embodiment.

FIG. 4 shows a cross-sectional view of a chip on film package with respect to a line I1-I1′ of FIG. 3.

FIG. 5 shows an enlarged top plan view of a region A of FIG. 3.

FIG. 6 shows a top plan view of a chip on film package according to an embodiment.

FIG. 7 shows a cross-sectional view of a chip on film package with respect to a line I2-I2′ of FIG. 6.

FIG. 8 shows a top plan view of a chip on film package according to an embodiment.

FIG. 9 shows a top plan view of a chip on film package according to an embodiment.

FIG. 10 shows a top plan view of a chip on film package according to an embodiment.

FIG. 11 shows a top plan view of a chip on film package according to an embodiment.

### DETAILED DESCRIPTION

Non-limiting example embodiments of the present disclosure will be described more fully hereinafter with reference to the accompanying drawings, in which example embodiments of the present disclosure are shown. As those skilled in the art would realize, the example embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings may be arbitrarily shown for better understanding and ease of description, and embodiments of the present disclosure are not limited thereto. In the drawings, the thickness of layers, films, panels, regions, etc., may be enlarged for clarity. The thicknesses of some layers and areas may be exaggerated for convenience of explanation.

It will be understood that when an element (e.g., a layer, film, region, or substrate) is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements present.

Unless explicitly described to the contrary, the word “comprise” (or “include”) and variations such as “comprises” (or “includes”) or “comprising” (or “including”), will be understood to imply the inclusion of stated elements but not the exclusion of any other elements.

The phrase “on a plane” means viewing the object portion from the top, and the phrase “on a cross-section” means viewing a cross-section of which the object portion is vertically cut from the side.

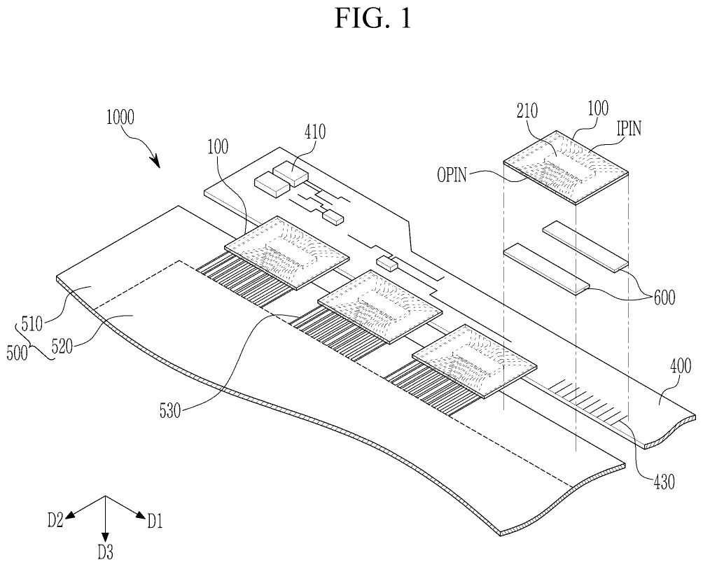

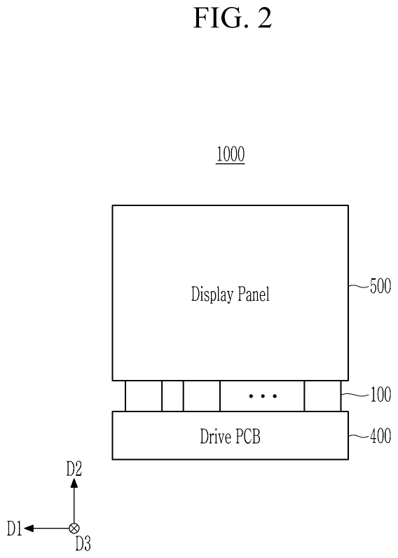

FIG. 1 shows a perspective view of an electronic device including a chip on film package according to an embodiment. FIG. 2 shows a block diagram of an electronic device including a chip on film package according to an embodiment.

The electronic device 1000 may be a display device. Referring to FIG. 1 and FIG. 2, the electronic device 1000 may include at least one chip on film package 100, a printed circuit board (PCB) 400, and a display panel 500. The chip on film package 100 may be disposed between the printed circuit board 400 and the display panel 500. The printed circuit board 400 may be connected to the display panel 500 by the chip on film package 100. The chip on film package 100 may receive signals output by the printed circuit board 400 and may transmit them to the display panel 500.

The chip on film package 100 may be a display driver integrated circuit (DDI) package including a semiconductor chip 210 for driving the electronic device 1000. However, without being limited thereto, the chip on film package 100 may have various types of modifications.

In several embodiments, when the chip on film package 100 is combined with an electronic device, other than a display device, and is then used, the semiconductor chip 210 may drive the electronic device.

At least one driving circuit chip 410 for applying power voltages and signals to the chip on film package 100 may be mounted on the printed circuit board 400.

The display panel 500 may be, for example, a liquid crystal display (LCD) panel, a light emitting diode (LED) panel, an organic LED (OLED) panel, and a plasma display panel (PDP). However, the display panel 500 may not be limited thereto and may be modifiable in many ways.

The chip on film package 100 may be connected to a driving connecting wire 430 of the printed circuit board 400 and a panel connecting wire 530 of the display panel 500.

In several embodiments, the chip on film packages 100 may be connected between the printed circuit board 400 and the display panel 500. For example, the electronic device 1000 may include multiple chip on film packages 100 when the display panel 500 provides wide screens, such as for television sets, or supports high resolution.

Differing from this, one chip on film package 100 may be connected between the printed circuit board 400 and the display panel 500. For example, the electronic device 1000 may include one chip on film package 100 when the display panel 500 provides a small screen, such as for a smartphone, or supports low resolution.

The chip on film package 100 may be connected to a first side of the display panel 500. In several embodiments, one or multiple chip on film packages 100 may be connected to at least two lateral surfaces of the display panel 500. For example, when one or multiple chip on film packages 100 are connected to two lateral surfaces of the display panel 500 that are connected to each other, the chip on film package 100 connected to a first lateral surface of the display panel 500 may be connected to gate lines of the display panel 500 to perform a function of a gate driver, and the chip on film package 100 connected to a second lateral surface of the display panel 500 may be connected to source lines of the display panel 500 and may perform a function of a source driver.

The display panel 500 may include a display area 520 and a non-display area 510 provided to at least the first side of the display area 520.

Pixels may be disposed in the display area 520. The pixels disposed in the display area 520 may be connected to the panel connecting wires 530, and may be operated according to the signal provided by the semiconductor chip 210 disposed on the chip on film package 100. The non-display area 510 displays no images. Drivers for driving the pixels disposed in the display area 520, pixels, and some of wires for connecting the drivers may be provided in the non-display area 510.

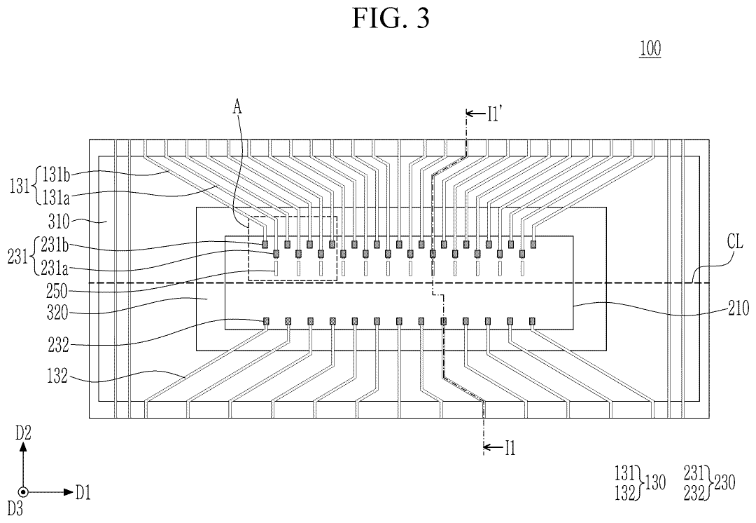

An input pin IPIN may be disposed on a first end of a substrate 110 (see FIG. 3) included in the chip on film package 100, and an output pin OPIN may be disposed on a second end thereof. The input pin IPIN and the output pin OPIN may be connected to the driving connecting wire 430 of the printed circuit board 400 and the panel connecting wire 530 of the display panel 500 by an anisotropic conductive layer 600.

The anisotropic conductive layer 600 may be, for example, an anisotropic conductive film or an anisotropic conductive paste. The anisotropic conductive layer 600 may have a structure in which conductive particles are dispersed in an insulating adhesive layer, and may have an anisotropic electric characteristic in which it becomes conductive in an electrode direction that is the perpendicular vertical direction when connected, and it may be insulated in the direction (e.g., the horizontal direction) between electrodes.

When heat and pressure are applied to the anisotropic conductive layer 600 to fuse the adhesive, the conductive particles may be arranged between the facing electrodes (e.g., between the input pin IPIN and the driving connecting wire 430 or between the output pin OPIN and the panel connecting wire 530) to generate conductivity, and an adhesive may be supplied between the adjacent electrodes so that they may be insulated.

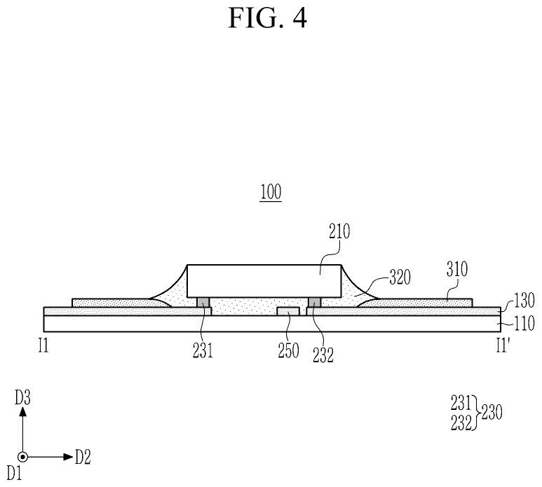

FIG. 3 and FIG. 4 show a chip on film package according to an embodiment. In detail, FIG. 3 shows a top plan view of a chip on film package according to an embodiment, and FIG. 4 shows a cross-sectional view of a chip on film package with respect to a line I1-I1′ of FIG. 3.

Referring to FIG. 3 and FIG. 4, the chip on film package 100 may include a substrate 110, a semiconductor chip 210 disposed on the substrate 110, wires 130 extending to an edge of the substrate 110 on a first side or a second side of the substrate 110 from an edge of the semiconductor chip 210 on a first side or a second side of the semiconductor chip 210, bumps 230 (e.g., first bumps 231 and second bumps 232) may be disposed between the wires 130 (or leads) and the semiconductor chip 210, and dummy patterns 250 spaced apart from at least some of the bumps 230.

The substrate 110 may be a flexible substrate. The substrate 110 may include an insulating material. For example, the substrate 110 may be a resin-based material made of polyimide, polyester, or other known materials, and may have flexibility. However, the materials included in the substrate 110 are not limited thereto and may be modifiable in many ways.

The semiconductor chip 210 may be disposed on the substrate 110. Referring to FIG. 3 and FIG. 4, the semiconductor chip 210 is shown to be disposed on a center portion of the substrate 110, but is not limited thereto, and the position of the semiconductor chip 210 on the substrate 110 may be changed in various ways. The semiconductor chip 210 may include a display driving integrated circuit (IC) for driving the electronic device 1000 (see FIG. 1).

The wires 130 may be disposed between the substrate 110 and the semiconductor chip 210. The semiconductor chip 210 may be connected to the wires 130 disposed on the substrate 110. Referring to FIG. 3 and FIG. 4, ends of each of the wires 130 may overlap with an edge of the semiconductor chip 210 in a third direction D3. The wires 130 may extend to an edge of the substrate 110 on a first side or a second side of the substrate 110 from a portion of the wires 130 overlapping with an edge of the semiconductor chip 210 on a first side or a second side of the semiconductor chip 210. Each of the wires 130 may extend to an edge of the substrate 110, and may be connected to the input pin IPIN or the output pin OPIN of the substrate 110 described with reference to FIG. 1. Referring to FIG. 3, each of the wires 130 may extend in a second direction D2 from a portion of the wires 130 overlapping with the semiconductor chip 210 in the third direction D3. However, without being limited thereto, each of the wires 130 may extend in a first direction D1 or a diagonal direction between the first direction D1 and the second direction D2 from a portion of the wires 130 overlapping with the semiconductor chip 210 in the third direction D3.

In detail, first wires 131 from among the wires 130 may extend to the edge of the substrate 110 on the first side of the substrate 110 from a portion of the first wires 131 overlapping with an edge of the semiconductor chip 210 on the first side of the semiconductor chip 210. The first wires 131 may be connected to the output pin OPIN (see FIG. 1) on the edge of the substrate 110 on the first side of the substrate 110. Second wires 132 from among the wires 130 may extend to an edge of the substrate 110 on the second side facing away from the first side of the substrate 110 from the portion of the second wires 132 overlapping with the edge of the semiconductor chip 210 on the first side of the semiconductor chip 210. The second wires 132 may be connected to the input pin IPIN on the edge of the substrate 110 on the second side of the substrate 110. In an embodiment, the semiconductor chip 210 may be connected to the display panel 500 described with reference to FIG. 1 through the first wires 131 and the output pin OPIN connected thereto, and may be connected to the printed circuit board 400 described with reference to FIG. 1 through the second wires 132 and the input pin IPIN connected thereto.

In an embodiment, the number of the first wires 131 may be greater than the number of the second wires 132, but is not limited thereto. Referring to FIG. 3, the first wires 131 may include inner wires 131a and outer wires 131b. The inner wires 131a may be connected to first internal bumps 231a to be described, and the outer wires 131b may be connected to first external bumps 231b to be described.

In an embodiment, extending lengths of the inner wires 131a and the outer wires 131b may be different from each other in a region in which the first wires 131 overlap with the semiconductor chip 210 in the third direction D3. For example, the extending length of the inner wire 131a may be greater than the extending length of the outer wire 131b in the region where the first wires 131 overlap with the semiconductor chip 210 in the third direction D3. Ends of each of the inner wires 131a may be disposed nearer than respective ends of the outer wires 131b to a center portion of the semiconductor chip 210. The inner wires 131a and the outer wires 131b may be alternately arranged in the first direction D1.

In an embodiment, the wires 130 may include a conductive material. For example, the wires 130 may include at least one from among copper (Cu) and aluminum (Al), and without being limited thereto, the wires 130 may include various types of conductive materials for electrically connecting the semiconductor chip 210 and the output pin OPIN (see FIG. 1) or the input pin IPIN (see FIG. 1).

In an embodiment, the wires 130 may further include other wires 130 for directly connecting the input pin IPIN and the output pin OPIN described with reference to FIG. 1.

Bumps 230 may be disposed between the wires 130 and the semiconductor chip 210. The bumps 230 may connect the semiconductor chip 210 and each of the wires 130. The bumps 230 may protrude toward the wires 130 by a predetermined thickness from a surface of the semiconductor chip 210 facing the wires 130. Referring to FIG. 3, each of the bumps 230 may be disposed on the first side of the semiconductor chip 210, or at least a portion of an edge of the second side facing the first side, which is not limited thereto. The bumps 230 may be disposed, for example, on the center portion of the semiconductor chip 210. Each of the bumps 230 are shown to have a quadrangular shape extending in the second direction D2 in a plan view, which is not limited thereto.

The bumps 230 may include first bumps 231 disposed between the first wires 131 and the semiconductor chip 210 and second bumps 232 disposed between the second wires 132 and the semiconductor chip 210.

The first bumps 231 may connect the first wires 131 and the semiconductor chip 210. The first bumps 231 may include the first internal bumps 231a connected to the inner wires 131a, and the first external bumps 231b connected to the outer wire 131b. The first internal bumps 231a may be spaced apart from each other in the first direction D1. The first external bumps 231b may be spaced apart from each other in the first direction D1. The first internal bumps 231a and the first external bumps 231b may be alternately arranged in the first direction D1. The first internal bumps 231a may be disposed nearer than the first external bumps 231b to the center portion of the semiconductor chip 210. In detail, the first internal bumps 231a may be disposed nearer than the first external bumps 231b to a virtual center line (CL) passing through the center portion of the semiconductor chip 210 and extending in the first direction D1.

The second bumps 232 may connect the second wires 132 and the semiconductor chip 210. The second bumps 232 may be spaced apart from each other in the first direction D1. The second bumps 232 are shown to be arranged in series in the first direction D1, differing from an alternating arrangement of the first bumps 231, but they are not limited thereto. For example, the second bumps 232 may be alternately arranged in the first direction D1 in a similar way to the first bumps 231.

In an embodiment, the bumps 230 may include conductive materials. For example, the bumps 230 may include gold (Au), and without being limited thereto, they may include various types of conductive materials.

The dummy patterns 250 may be disposed on the substrate 110. The dummy patterns 250 may be disposed on a portion of the substrate 110 that is near the wires 130. Each of the dummy patterns 250 may face at least one of the wires 130. Referring to FIG. 3, each of the dummy patterns 250 may face an inner wire 131a from among the wires 130. Each of the dummy patterns 250 may be spaced apart from first ends of each of the inner wires 131a in the second direction D2 by predetermined intervals. Widths of each of the dummy patterns 250 in the first direction D1 may be substantially equal to the width of the inner wire 131a in the first direction D1.

The dummy patterns 250 may be disposed near the wires 130 on the substrate 110, and a physical stress received by the wires 130 may be reduced in a process after the dummy pattern 250 is formed on the substrate 110. For example, a cleaning solution may be prevented from being sprayed on to the wires 130 in a cleaning process, and hence, the wires 130 may be prevented from peeling off from the surface of the substrate 110. In another way, during the process for manufacturing the chip on film package 100, when friction is generated between a surface of the substrate 110 on which the wires 130 are formed and another film or layer, the wires 130 may be prevented from being delaminated from the substrate 110.

The dummy patterns 250 may be spaced apart from each other in the first direction D1. When gaps among the dummy patterns 250 are substantially narrow, it may hinder a flow of the insulating material during a process for filling a second protection layer 320 to be described between the semiconductor chip 210 and the substrate 110, and in this case, a void may be formed between the semiconductor chip 210 and the substrate 110 in a comparative embodiment. Hence, the dummy patterns 250 may be spaced apart from each other by a predetermined gap on the substrate 110. In an embodiment, the dummy patterns 250 may be spaced apart from each other by substantially the same distance as the distance by which the inner wires 131a or the first internal bumps 231a are spaced in the first direction D1.

In an embodiment, the dummy patterns 250 may not overlap with the outer wires 131b and/or the first external bumps 231b in the second direction D2. In an embodiment, the dummy patterns 250 may not be disposed in a region overlapping with the outer wires 131b and/or the first external bumps 231b in the second direction D2 on the substrate 110.

Each of the dummy patterns 250 may extend in substantially the same direction as the direction in which the wires 130 extend in a region overlapping with the semiconductor chip 210 in the third direction D3. Referring to FIG. 3, each of the dummy patterns 250 may have a quadrangular shape extending in the second direction D2, but are not limited thereto.

The dummy patterns 250 may be disposed near at least some of the bumps 230. The dummy patterns 250 may be spaced apart from at least some of the first bumps 231, respectively, in the second direction D2. In an embodiment, each of the dummy patterns 250 may be spaced apart from an first internal bump 231a from among the first bumps 231 in the second direction D2. Each of the dummy patterns 250 may be disposed nearer than the first internal bumps 231a to the center portion of the semiconductor chip 210. Each of the dummy patterns 250 may be disposed between the center portion of the semiconductor chip 210 and the bumps 230. In detail, each of the dummy patterns 250 may be disposed nearer than the first internal bumps 231a to the virtual center line (CL) passing through the center portion of the semiconductor chip 210 and extending in the first direction D1.

In an embodiment, the dummy patterns 250 may be simultaneously formed with the wires 130 in the same process. The dummy patterns 250 may be disposed on the same layer as the wires 130. The dummy patterns 250 may include the same material as the wires 130. For example, the dummy patterns 250 may include at least one from among copper (Cu) and aluminum (Al).

The dummy patterns 250 may be formed in a different process from the wires 130. The dummy pattern 250 may include different materials from the wires 130. For example, the dummy patterns 250 may include an insulating material such as silicon oxide (SiO₂), silicon nitride (SiN_{X}), or silicon oxynitride (SiON).

The chip on film package 100 may further include a first protection layer 310 and a second protection layer 320 disposed on the substrate 110.

The first protection layer 310 may cover at least a portion of upper surfaces and lateral surfaces of each of the wires 130. Predetermined regions of each of the wires 130 may not be covered by the first protection layer 310 but may be exposed. In detail, referring to FIG. 3 and FIG. 4, ends of each of the wires 130 may not be covered by the first protection layer 310 and may be exposed.

In the entire region of the first wires 131, the first bumps 231 may be disposed on a first end of the first wires 131 not covered by the first protection layer 310, and each of the first wires 131 may be connected to the semiconductor chip 210 by the first bumps 231. In the entire region of the first wires 131, at least one output pin OPIN may be disposed on a second end of the first wires 131 not covered by the first protection layer 310, and each of the first wires 131 may be connected to the display panel 500 described with reference to FIG. 1 through the at least one output pin OPIN.

In the entire region of the second wires 132, the second bump 232 may be disposed on the first end of the second wires 132 not covered by the first protection layer 310, and each of the second wires 132 may be connected to the semiconductor chip 210 by the second bumps 232. In the entire region of the second wires 132, at least one input pin IPIN may be disposed on the second end of the second wires 132 not covered by the first protection layer 310, and each of the second wires 132 may be connected to the printed circuit board 400 described with reference to FIG. 1 through the at least one input pin IPIN.

The first protection layer 310 may include an insulating material. For example, the first protection layer 310 may include an insulating material such as silicon oxide (SiO₂), silicon nitride (SiN_{X}), or silicon oxynitride (SiON). However, the material included in the first protection layer 310 is not limited thereto, and may include various types of materials insulating the wires 130 from an outside and protecting the same.

The second protection layer 320 may cover at least a portion of the semiconductor chip 210, and may cover a peripheral portion of the semiconductor chip 210. Referring to FIG. 4, the second protection layer 320 may cover part of a portion of the first protection layer 310 that is near the semiconductor chip 210. The second protection layer 320 may cover a portion of the wires 130 disposed near the semiconductor chip 210 and not covered by the first protection layer 310. The second protection layer 320 may cover a lateral surface of the semiconductor chip 210. Referring to FIG. 4, the second protection layer 320 may fill a space between the semiconductor chip 210 and the substrate 110. The second protection layer 320 may cover lateral surfaces of the bumps 230 disposed between the semiconductor chip 210 and the substrate 110, and upper surfaces and lateral surfaces of each of the dummy patterns 250.

In an embodiment, the second protection layer 320 may be formed by applying an insulating material in a liquid state having a predetermined level of viscosity around the semiconductor chip 210, and curing the insulating material. The insulating material in a liquid state may be applied on the semiconductor chip 210, may pass through among the wires 130 and among the dummy patterns 250, and may fill a gap between the lower surface of the semiconductor chip 210 and the substrate 110. In an embodiment, the dummy patterns 250 may be arranged on the substrate 110 with sufficient gaps between the dummy patterns 250 so that the insulating material may flow in the process for forming the second protection layer 320.

The second protection layer 320 may include an insulating material. For example, the second protection layer 320 may include an insulating polymer. For example, the second protection layer 320 may include an epoxy-based polymer. However, the material included by the second protection layer 320 is not limited thereto, and may be changed in many ways.

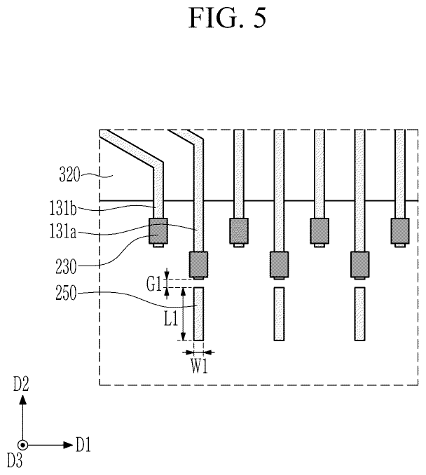

FIG. 5 shows an enlarged top plan view of a region A of FIG. 3. To reduce the stress received by the wires 130 in the process for manufacturing the chip on film package 100, the dummy patterns 250 may be disposed near each other in the first direction D1 while facing the inner wires 131a in the second direction D2. However, when the dummy pattern 250 is substantially close to the inner wire 131a, a short-circuit may be generated between the dummy pattern 250 and the inner wire 131a. Therefore, the dummy pattern 250 may be spaced apart from the inner wire 131a by a predetermined gap G1. In an embodiment, the gap G1 between the dummy pattern 250 and the inner wire 131a may be equal to or greater than about 10 μm and equal to or less than about 100 μm.

In several embodiments, each of the dummy patterns 250 may have a quadrangular shape extending in the second direction D2. Referring to FIG. 5, a length L1 of the dummy pattern 250 in the second direction D2 may be greater than a width W1 of the dummy pattern 250 in the first direction D1. In an embodiment, the length L1 of the dummy pattern 250 in the second direction D2 may be greater than the gap G1 between the dummy pattern 250 and the inner wire 131a. In an embodiment, the length L1 of the dummy pattern 250 in the second direction D2 may be equal to or greater than about 50 μm.

In an embodiment, the widths W1 of each of the dummy patterns 250 in the first direction D1 may be substantially equal to the widths of each of the wires 130 in the first direction D1. The widths W1 of each of the dummy patterns 250 in the first direction D1 may be substantially equal to the width of the inner wire 131a in the first direction D1. In an embodiment, the widths W1 of each of the dummy patterns 250 in the first direction D1 may be equal to or greater than about 7 μm and equal to or less than about 20 μm.

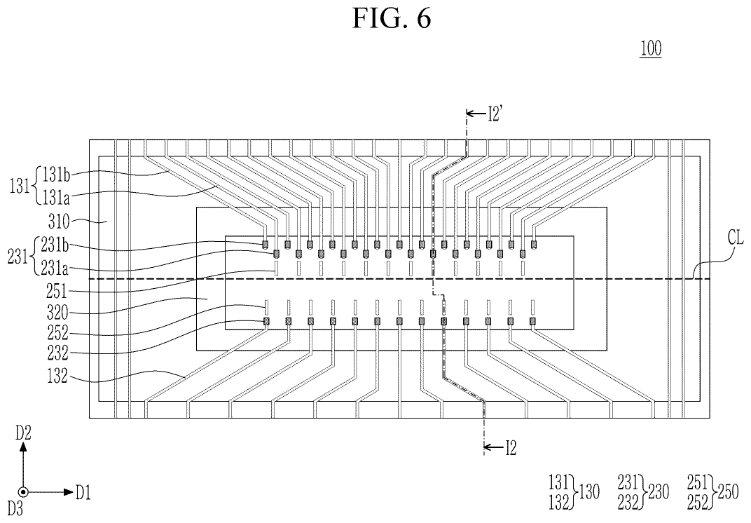

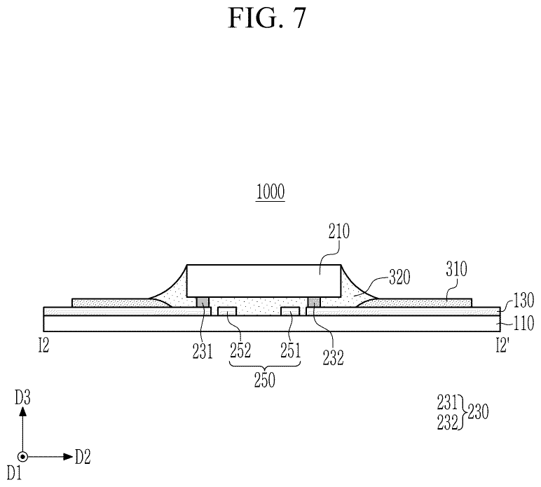

FIG. 6 and FIG. 7 show a chip on film package according to several embodiments. In detail, FIG. 6 shows a top plan view of a chip on film package according to an embodiment, and FIG. 7 shows a cross-sectional view of a chip on film package with respect to a line I2-I2′ of FIG. 6. Differences between the chip on film package according to an embodiment and the previously described embodiments of the present disclosure will be mainly described. The chip on film package according to an embodiment may be partly different from the previously described embodiments of the present disclosure in that it includes dummy patterns (e.g., first dummy patterns 251 and second dummy patterns 252) that are arranged at different positions.

Referring to FIG. 6 and FIG. 7, the chip on film package may include first dummy patterns 251 and second dummy patterns 252.

The first dummy patterns 251 may be disposed near the inner wire 131a and/or the first internal bumps 231a. The arrangement and shape of the first dummy pattern 251 may be substantially the same as the dummy pattern 250 described with reference to FIG. 3 to FIG. 5, and therefore repeated descriptions thereof may be omitted.

The second dummy patterns 252 may face the second wires 132. Each of the second dummy patterns 252 may be spaced apart from respective ends of the second wires 132 by predetermined intervals in the second direction D2. The widths of each of the second dummy patterns 252 in the first direction D1 may be substantially equal to the width of the second wire 132 in the first direction D1.

The second dummy patterns 252 may reduce the physical stress to be received by the second wires 132 in the process after the second dummy pattern 252 is formed on the substrate 110.

The second dummy patterns 252 may be spaced apart from each other in the first direction D1. In an embodiment, the second dummy patterns 252 may be spaced apart from each other by substantially the same distance as the distance by which the second wires 132 or the second bump 232 are spaced apart in the first direction D1.

In an embodiment, the second dummy patterns 252 may not overlap with the first dummy patterns 251 in the second direction D2. In an embodiment, the second dummy patterns 252 may not be disposed in a region overlapping with the first dummy pattern 251 in the second direction D2 on the substrate 110.

Each of the second dummy patterns 252 may extend in substantially the same direction as the direction in which the second wires 132 extend in the region overlapping with the semiconductor chip 210 in the third direction D3. Referring to FIG. 6, each of the second dummy patterns 252 may have a quadrangular shape extending in the second direction D2, but are not limited thereto.

The second dummy patterns 252 may be disposed near the second bumps 232. Referring to FIG. 6, the second dummy patterns 252 may be spaced apart from each of the second bumps 232 in the second direction D2. Each of the second dummy patterns 252 may be disposed nearer than the second bumps 232 to the center portion of the semiconductor chip 210, compared to. Each of the second dummy patterns 252 may be disposed between the center portion of the semiconductor chip 210 and the second bumps 232. In detail, each of the second dummy patterns 252 may be disposed nearer than the second bumps 232 to the virtual center line (CL) passing through the center portion of the semiconductor chip 210 and extending in the first direction D1.

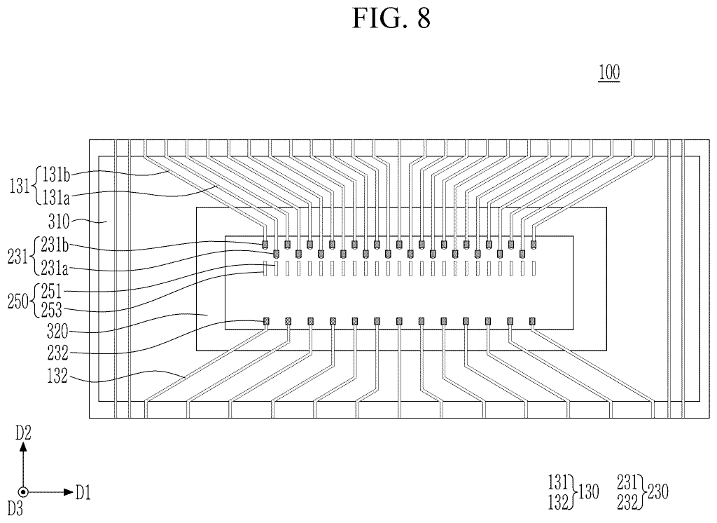

FIG. 8 shows a chip on film package 100 according to several embodiments. In detail, FIG. 8 shows a top plan view of a chip on film package according to an embodiment. The chip on film package 100 according to an embodiment has many of the same aspects as the previously described embodiments of the present disclosure, and so the differences from the previously described embodiments of the present disclosure will now be mainly described. The chip on film package 100 may be partly different from the previously described embodiments of the present disclosure in that it includes third dummy patterns 253.

Referring to FIG. 8, the chip on film package 100 may include first dummy patterns 251 and third dummy patterns 253.

The first dummy patterns 251 may be disposed near the inner wire 131a and/or the first internal bump 231a. The arrangement and shape of the first dummy pattern 251 are substantially the same as the dummy pattern 250 described with reference to FIG. 3 to FIG. 5, which will not be described.

The third dummy patterns 253 may face the outer wires 131b. Each of the third dummy patterns 253 may be spaced apart from respective ends of the respective outer wires 131b by predetermined intervals in the second direction D2.

In an embodiment, the third dummy patterns 253 and the first dummy patterns 251 may be alternately arranged in the first direction D1. The third dummy patterns 253 and the first dummy patterns 251 may be arranged in a line in the first direction D1. In an embodiment, the gaps between the respective third dummy patterns 253 and the first end of the outer wire 131b facing the same may be greater than the gaps between the respective first dummy patterns 251 and the first end of the inner wire 131a.

In an embodiment, the third dummy patterns 253 may be spaced apart from each other by substantially the same distance as the distance by which the outer wires 131b are spaced apart in the first direction D1. The respective third dummy patterns 253 may extend in substantially the same direction as the direction in which the outer wires 131b extend in the region overlapping with the semiconductor chip 210 in the third direction D3.

The third dummy patterns 253 may be disposed near the first external bumps 231b. Referring to FIG. 8, the third dummy patterns 253 may be spaced apart from the first external bumps 231b in the second direction D2. The respective third dummy patterns 253 may be disposed nearer than the first external bumps 231b to the center portion of the semiconductor chip 210. The respective third dummy patterns 253 may be disposed between the center portion of the semiconductor chip 210 and the outer wires 131b. In detail, the respective third dummy patterns 253 may be disposed nearer than the outer wires 131b to the virtual center line (CL) passing through the center portion of the semiconductor chip 210 and extending in the first direction D1.

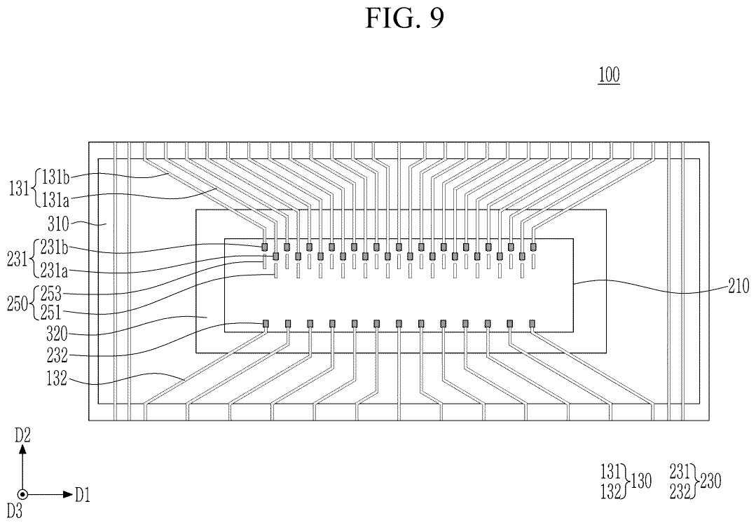

FIG. 9 shows a chip on film package 100 according to several embodiments. In detail, FIG. 9 shows a top plan view of a chip on film package according to an embodiment. The chip on film package 100 according to an embodiment has many of the same aspects as the previously described embodiments of the present disclosure, and so the differences from the previously described embodiments of the present disclosure will now be mainly described. Regarding the chip on film package 100, the positions on which the third dummy patterns 253 are arranged may be partly different from the embodiment described with reference to FIG. 8.

Referring to FIG. 9, the respective third dummy patterns 253 may be spaced apart from the ends of the respective outer wires 131b by predetermined intervals in the second direction D2. In an embodiment, the gaps between the third dummy patterns 253 and the outer wires 131b facing the same may be substantially equal to the gaps between the first dummy patterns 251 and the inner wires 131a facing the same.

In an embodiment, the third dummy patterns 253 and the first dummy patterns 251 may be alternately arranged in the first direction D1. The third dummy patterns 253 and the first dummy patterns 251 may be alternately arranged in the first direction D1.

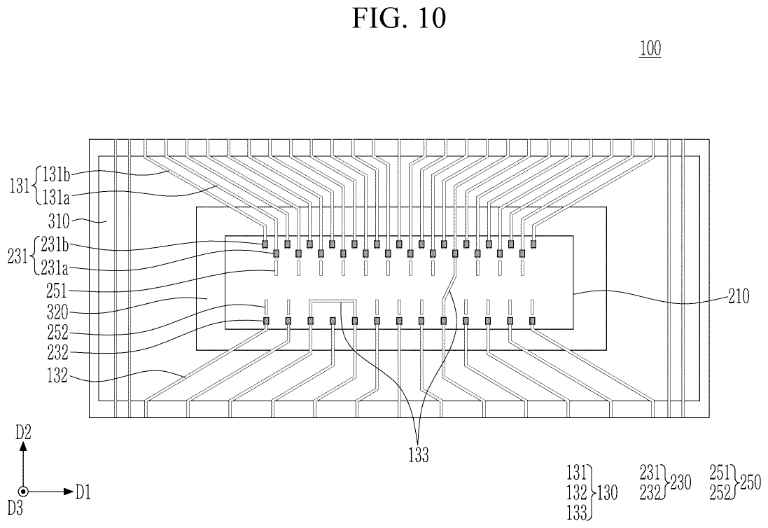

FIG. 10 shows a chip on film package 100 according to several embodiments. In detail, FIG. 10 shows a top plan view of a chip on film package according to an embodiment. The chip on film package 100 according to an embodiment has many of the same aspects as the previously described embodiments of the present disclosure, and so the differences from the previously described embodiments of the present disclosure will now be mainly described. The chip on film package 100 according to an embodiment may be partly different from the embodiment described with reference to FIG. 6 and FIG. 7 in that it includes the third wire 133.

Referring to FIG. 10, the chip on film package 100 may include a first dummy patterns 251 arranged to face the inner wires 131a, and second dummy patterns 252 arranged to face the second wires 132.

The third wires 133 shown in FIG. 10 may be a film level routing wire. In an embodiment, the respective third wires 133 may connect any two from among the first wires 131 and the second wires 132 (e.g., two first wires 131, two second wires 132, or one first wire 131 and one second wire 132) in the region overlapping with the semiconductor chip 210 in the third direction D3.

In detail, the third wire 133 may connect two different second wires 132 in the region overlapping with the semiconductor chip 210 in the third direction D3. The dummy patterns (e.g., the first dummy patterns 251 and the second dummy patterns 252) may not be disposed in a region overlapping with the second wires 132 connected to the third wire 133 in the second direction D2.

The third wire 133 may connect the first wire 131 and the second wires 132 in the region overlapping with the semiconductor chip 210 in the third direction D3. The dummy patterns (e.g., the first dummy patterns 251 and the second dummy patterns 252) may not be disposed in a region overlapping with the first wire 131 and the second wire 132 connected to the third wire 133 in the second direction D2.

Differing from what is shown in FIG. 10, the third wire 133 may connect the two different first wires 131 to each other. The dummy patterns (e.g., the first dummy patterns 251 and the second dummy patterns 252) may not be disposed in a region overlapping with the first wires 131 connected to the third wire 133 in the second direction D2.

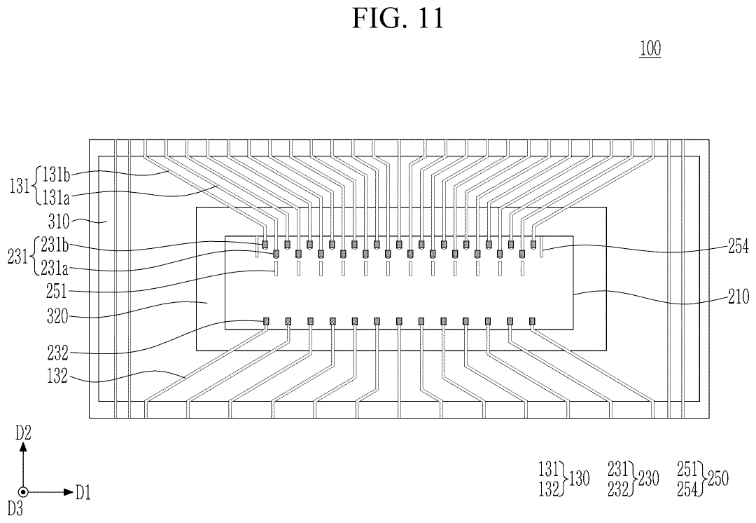

FIG. 11 shows a chip on film package 100 according to several embodiments. In detail, FIG. 11 shows a top plan view of a chip on film package according to an embodiment. The chip on film package 100 according to an embodiment has many of the same aspects as the previously described embodiments of the present disclosure, and so the differences from the previous embodiments will now be mainly described. The chip on film package 100 may be partly different from the previously described embodiments of the present disclosure in that it further includes fourth dummy patterns 254.

The fourth dummy pattern 254 may be disposed on first sides of outermost ones of the first wires 131. In detail, the fourth dummy pattern 254 may be disposed on the first sides of outermost ones of the first wires 131 in the first direction D1 in the region overlapping with the semiconductor chip 210 in the third direction D3. Referring to FIG. 11, fourth dummy patterns 254 may be respectively disposed on the left of the leftmost one of the first wires 131 and on the right of the rightmost one of the first wires 131.

In an embodiment, the fourth dummy patterns 254 may be formed on lateral surfaces of the first wires 131, and may reduce the physical stress received by the wires 130 in the subsequent process. In an embodiment, the fourth dummy patterns 254 may extend in the second direction D2.

In an embodiment, the fourth dummy patterns 254 may overlap with the first wires 131 in the first direction D1 in the region in which the semiconductor chip 210 overlaps with the substrate 110 in the third direction D3. In the region in which the semiconductor chip 210 overlaps with the substrate 110 in the third direction D3, the length of the fourth dummy patterns 254 extending in the second direction D2 may be equal to or greater than the length of the first wire 131 extending in the second direction D2.

While non-limiting example embodiments of the present disclosure have been described with reference to the accompanying drawings, it is to be understood that the present disclosure is not limited to the example embodiments. Instead, various modifications and equivalent arrangements are included within the spirit and scope of the present disclosure.

What is claimed is:

1. A chip on film package comprising:
a substrate;
a semiconductor chip on the substrate;
first wires extending, on the substrate, to an edge of a first side of the substrate from a portion of the first wires overlapping with an edge of a first side of the semiconductor chip;
second wires extending, on the substrate, to an edge of a second side of the substrate from a portion of the second wires overlapping with an edge of a second side of the semiconductor chip;
first bumps connecting the first wires and the semiconductor chip;
first dummy patterns spaced apart from at least some of the first bumps, the first dummy patterns being nearer than the first bumps to a center portion of the semiconductor chip,
wherein the first bumps comprise:
first external bumps spaced apart from each other in a first direction that is parallel to the edge of the first side of the semiconductor chip; and
first internal bumps spaced apart from each other in the first direction, the first internal bumps being nearer than the first external bumps to the center portion of the semiconductor chip, and
wherein the first dummy patterns are respectively spaced apart from the first internal bumps in a second direction that is perpendicular to the first direction.

2. The chip on film package of claim 1, wherein the first dummy patterns do not overlap with the first external bumps in the second direction.

3. The chip on film package of claim 1, wherein the first dummy patterns extend in the second direction and are spaced apart in the second direction from a center line passing through the center portion of the semiconductor chip, and
wherein the first dummy patterns are between the center line and the first bumps.

4. The chip on film package of claim 1, further comprising:
second bumps connecting the second wires and the semiconductor chip; and
second dummy patterns spaced apart from the second bumps in the second direction, the second dummy patterns being nearer than the second bumps to the center portion of the semiconductor chip.

5. The chip on film package of claim 4, wherein the second dummy patterns do not overlap with the first dummy patterns in the second direction.

6. The chip on film package of claim 4, further comprising:
a third wire connecting two of the first wires, two of the second wires, or one of the first wires and one of the second wires,
wherein the first dummy patterns or the second dummy patterns are not disposed in a region overlapping with, in the second direction, a location in which any of the two of the first wires, two of the second wires, or the one of the first wires and the one of the second wires is connected to the third wire.

7. The chip on film package of claim 1, wherein each of the first dummy patterns extend in the second direction, and
wherein lengths of the first dummy patterns in the second direction are greater than widths of the first dummy patterns in the first direction.

8. The chip on film package of claim 7, wherein the lengths of the first dummy patterns in the second direction are larger than a gap between one of the first wires and one of the first dummy patterns nearest to the one of the first wires, among the first dummy patterns.

9. The chip on film package of claim 1, wherein a gap between one of the first wires and one of the first dummy patterns nearest to the one of the first wires, among the first dummy patterns, is equal to or greater than 10 μm and equal to or less than 100 μm.

10. The chip on film package of claim 1, wherein widths of the first dummy patterns in the first direction are equal to or greater than 7 μm and equal to or less than 20 μm.

11. The chip on film package of claim 1, wherein a width of one of the first dummy patterns in the first direction is less than widths of each of the first bumps in the first direction.

12. The chip on film package of claim 1, wherein widths of each of the first dummy patterns in the first direction are equal to a width of one of the first wires in the first direction.

13. The chip on film package of claim 1, wherein the first dummy patterns and the first wires comprise a same material as each other.

14. The chip on film package of claim 1, wherein the first wires are spaced apart from each other in the first direction, and
the chip on film package further comprises a third dummy pattern at an outer side of an outermost first wire among the first wires.

15. The chip on film package of claim 14, wherein the third dummy pattern extends in the second direction, and
wherein a length of the third dummy pattern in the second direction is equal to or greater than a length, in the second direction, of an entire portion of one of the first wires that overlaps with the semiconductor chip in a third direction, perpendicular to the first direction and the second direction.

16. An electronic device comprising:
a printed circuit board; and
a chip on film package comprising:
an output pin on a first side of the chip on film package; and
an input pin on a second side of the chip on film package, the input pin connecting the chip on film package and the printed circuit board;
a substrate;
a semiconductor chip on the substrate;
first wires extending, on the substrate, to an edge of a first side of the substrate from a portion of the first wires overlapping with an edge of a first side of the semiconductor chip, wherein at least one of the first wires is connected to the output pin;
second wires extending, on the substrate, to an edge of a second side of the substrate from a portion of the second wires overlapping with an edge of a second side of the semiconductor chip, wherein at least one of the second wires is connected to the input pin;
first bumps connecting the first wires and the semiconductor chip; and
first dummy patterns spaced apart from at least some of the first bumps, the first dummy patterns being nearer than the first bumps to a center portion of the semiconductor chip,
wherein the first bumps comprise:
first external bumps spaced apart from each other in a first direction that is parallel to the edge of the first side of the semiconductor chip; and
first internal bumps spaced apart from each other in the first direction, the first internal bumps being nearer than the first external bumps to the center portion of the semiconductor chip, and
wherein the first dummy patterns are respectively spaced apart from the first internal bumps in a second direction that is perpendicular to the first direction.

17. The electronic device of claim 16, wherein the first dummy patterns do not overlap with the first external bumps in the second direction.

18. The electronic device of claim 16, further comprising
second bumps connecting the second wires and the semiconductor chip; and
second dummy patterns spaced apart from the second bumps in the second direction, the second dummy patterns being nearer than the second bumps to the center portion of the semiconductor chip.

19. The electronic device of claim 18, further comprising a third wire connecting two of the first wires, two of the second wires, or one of the first wires and one of the second wires,
wherein the first dummy patterns and the second dummy patterns are not disposed in a region overlapping with, in the second direction, a location in which any of the two of the first wires, two of the second wires, or the one of the first wires and the one of the second wires is connected to the third wire.

20. A chip on film package comprising:
a substrate;
a semiconductor chip on the substrate;
first wires extending, on the substrate, to an edge of a first side of the substrate from a portion first of the first wires overlapping with an edge of a first side of the semiconductor chip;
second wires extending, on the substrate, to an edge of a second side of the substrate from a portion of the second wires overlapping with an edge of a second side of the semiconductor chip;
a first protection layer on at least a region of the first wires and the second wires;
a second protection layer in a gap between the substrate and the semiconductor chip;
first bumps connecting the first wires and the semiconductor chip;
second bumps connecting the second wires and the semiconductor chip; and
first dummy patterns spaced apart from at least some of the first bumps, the first dummy patterns being nearer than the first bumps to a center portion of the semiconductor chip,
wherein the first bumps comprise:
first external bumps spaced apart from each other in a first direction that is parallel to the edge of the first side of the semiconductor chip; and
first internal bumps spaced apart from each other in the first direction, the first internal bumps being nearer than the first external bumps to the center portion of the semiconductor chip, and
wherein each of the first dummy patterns comprise a quadrangular shape extending in a second direction that is perpendicular to the first direction, and the first dummy patterns are respectively spaced apart from the first internal bumps in the second direction.
